(19) United States
(12) Patent Application Publication
(10) Pub. No.: US 2025/0227945 A1
(43) Pub. Date: Jul. 10, 2025

(54) HETEROJUNCTION BIPOLAR TRANSISTOR DEVICE

(71) Applicant: WIN SEMICONDUCTORS CORP., TAOYUAN CITY (TW)

(72) Inventors: Yu-An LIAO, TAOYUAN CITY (TW); Rong-Hao SYU, TAOYUAN CITY (TW); Shu-Hsiao TSAI, TAOYUAN CITY (TW)

(21) Appl. No.: 18/405,120

(22) Filed: Jan. 5, 2024

(51) Int. Cl. H01L 29/737; H01L 23/528; H01L 27/06; H01L 29/08; H01L 29/10; H01L 29/417; H01L 29/66

(52) U.S. Cl. CPC H10D 10/821; H01L 23/5286; H10D 10/021; H10D 62/136; H10D 62/138; H10D 62/177; H10D 64/231; H10D 84/615

(57) ABSTRACT

A heterojunction bipolar transistor device includes a substrate, a metallic sub-collector layer, a collector layer, a base layer, an emitter layer, a base electrode, and a plurality of emitter strips. The metallic sub-collector layer is formed over the substrate. The collector layer is formed over the metallic sub-collector layer. The base layer is formed over the collector layer. The emitter layer is formed over the base layer. The base electrode is formed over the base layer and includes a plurality of base fingers. The plurality of emitter strips are formed over the emitter layer and are arranged alternately with the plurality of base fingers.

### BACKGROUND

### Technical Field

Embodiments of the present disclosure relates to semiconductor technology, and in particular to a heterojunction bipolar transistor device.

### Description of the Related Art

The semiconductor industry has experienced exponential growth. Technological advances in semiconductor design have produced generations of semiconductor devices (e.g., transistors) where each generation can work more efficiently than the previous generation. The progress generally provides benefits by increasing production efficiency and lowering associated costs. For these advances to be realized, developments in semiconductor design and manufacturing are needed.

However, although existing semiconductor devices generally meet requirements, they have not been satisfactory in every respect. For example, in a heterojunction bipolar transistor device, several unit cells may be connected in parallel to make a power cell. However, this would increase the required area. Therefore, further improvements to the heterojunction bipolar transistor device are required.

### BRIEF SUMMARY

Heterojunction bipolar transistor devices are provided. An exemplary embodiment of a heterojunction bipolar transistor device includes a substrate, a metallic sub-collector layer, a collector layer, a base layer, an emitter layer, a base electrode, and a plurality of emitter strips. The metallic sub-collector layer is formed over the substrate. The collector layer is formed over the metallic sub-collector layer. The base layer is formed over the collector layer. The emitter layer is formed over the base layer. The base electrode is formed over the base layer and includes a plurality of base fingers. The plurality of emitter strips are formed over the emitter layer and are arranged alternately with the plurality of base fingers.

Another embodiment of a heterojunction bipolar transistor device includes a substrate, a collector mesa, a base mesa, a plurality of emitter mesas, and a base electrode. The collector mesa is formed on the substrate and includes a metallic sub-collector layer. The base mesa is formed on the collector mesa. The plurality of emitter mesas are formed on the base mesa. The base electrode is formed on the base mesa and includes a plurality of base fingers arranged alternately with the plurality of emitter mesas.

### BRIEF DESCRIPTION OF THE DRAWINGS

The present disclosure can be more fully understood by reading the subsequent detailed description and examples with references made to the accompanying drawings, wherein:

FIG. 1 is a cross-sectional view of an exemplary heterojunction bipolar transistor device in accordance with some embodiments of the present disclosure;

FIGS. 2A to 2G are cross-sectional views of various stages of manufacturing an exemplary heterojunction bipolar transistor device in accordance with some embodiments of the present disclosure;

FIG. 3 is a top view of an exemplary heterojunction bipolar transistor device in accordance with some embodiments of the present disclosure;

FIG. 4 is a top view of an exemplary heterojunction bipolar transistor device in accordance with some embodiments of the present disclosure;

FIG. 5 is a cross-sectional view of an exemplary heterojunction bipolar transistor device in accordance with some embodiments of the present disclosure; and

FIG. 6 is a top view of an exemplary heterojunction bipolar transistor device in accordance with some embodiments of the present disclosure.

### DETAILED DESCRIPTION

The following description is made for the purpose of illustrating the general principles of the present disclosure and should not be taken in a limiting sense. The scope of the present disclosure is best determined by reference to the appended claims.

The present disclosure will be described with respect to particular embodiments and with reference to certain drawings, but the disclosure is not limited thereto and is only limited by the claims. The drawings described are only schematic and are non-limiting. In the drawings, the size of some of the elements may be exaggerated for illustrative purposes and not drawn to scale. The dimensions and the relative dimensions do not correspond to actual dimensions in the practice of the disclosure.

It should be understood that when an element, such as a layer, region or substrate, is referred to as being “on” or extending “onto” another element, the element can be directly on or extend directly onto the other element or intervening elements may also be present. It should also be understood that when an element is referred to as being “connected” or “coupled” to another element, it can be directly connected or coupled to the other element or intervening elements may be present.

It should be understood that, although the terms “first, second, etc.” may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present disclosure.

Unless otherwise defined, all terms (including technical and scientific terms) used herein have the same meaning as commonly understood by one of ordinary skill in the art to which the present disclosure belongs. It should be further understood that terms, such as those defined in commonly used dictionaries, should be interpreted as having a meaning that is consistent with their meaning in the context of the relevant art and will not be interpreted in an idealized or overly formal sense unless expressly so defined herein.

The term “cover” may be defined as at least partially overlap when viewing from above. The features of the embodiments may be modified or reorganized to form a new combination as a new embodiment. Furthermore, the description of “a first element extending through a second element” may include embodiments in which the first element is disposed in the second element and extends from a side of the second element to an opposite side of the second element, wherein a surface of the first element may be substantially leveled with a surface of the second element, or a surface of the first element may be outside a surface of the second element.

The spatially relative descriptors of one element and another element may change as the structure is operated or used in different orientations. In addition, the present disclosure may repeat reference numerals and/or letters in the various embodiments. This repetition is for simplicity and clarity and does not in itself dictate a relationship between the various embodiments discussed.

In describing one or more of these embodiments, the present disclosure may offer several advantages over prior art devices. In the discussion of the advantages or benefits that follows it should be noted that these benefits and/or results may be present in some embodiments, but are not required.

A heterojunction bipolar transistor (HBT) device including a metallic sub-collector layer is described in accordance with some embodiments of the present disclosure. The HBT device may include a plurality of emitter electrodes disposed directly over the single metallic sub-collector layer, so that the power cell can be achieved without increasing the parasitic capacitance. Furthermore, an emitter shunt and a collector shunt can be achieved simultaneously. In addition, the occupied area and the number of the collector contact can be reduced.

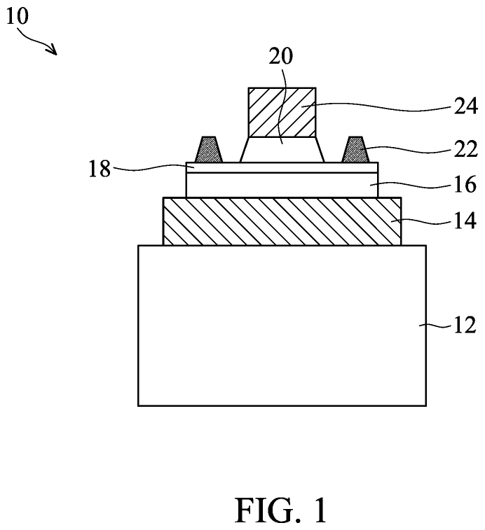

FIG. 1 is a cross-sectional view of a HBT device 10, in accordance with some embodiments. The HBT device 10 may include a substrate 12, a sub-collector layer 14, a collector layer 16, a base layer 18, an emitter layer 20, base electrodes 22, and a metal layer 24. The sub-collector layer 14, the collector layer 16, the base layer 18, and the emitter layer 20 may be sequentially formed over the substrate 12. The base electrodes 22 may be formed on the base layer 18 and adjacent to the emitter layer 20. The metal layer 24 may be formed on the emitter layer 20.

In some embodiments, the sub-collector layer 14 is formed of metal, so that the resistance contributed by a lateral epitaxial would substantially not exist, and the parasitic capacitance between the metal layer 24 and the metal of the sub-collector layer 14 would be reduced. Furthermore, an emitter shunt can be achieved from above the HBT device 10 while a collector shunt can be achieved from below the HBT device 10.

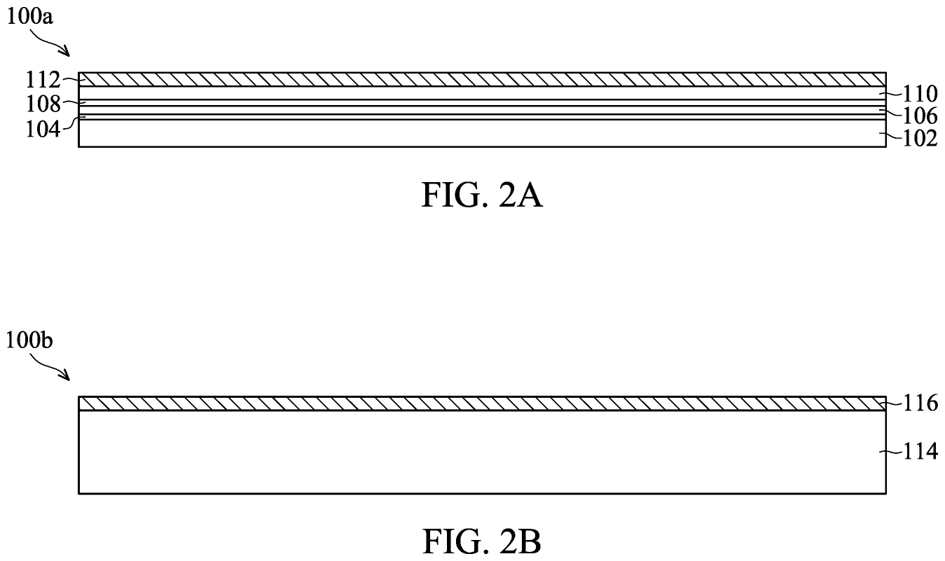

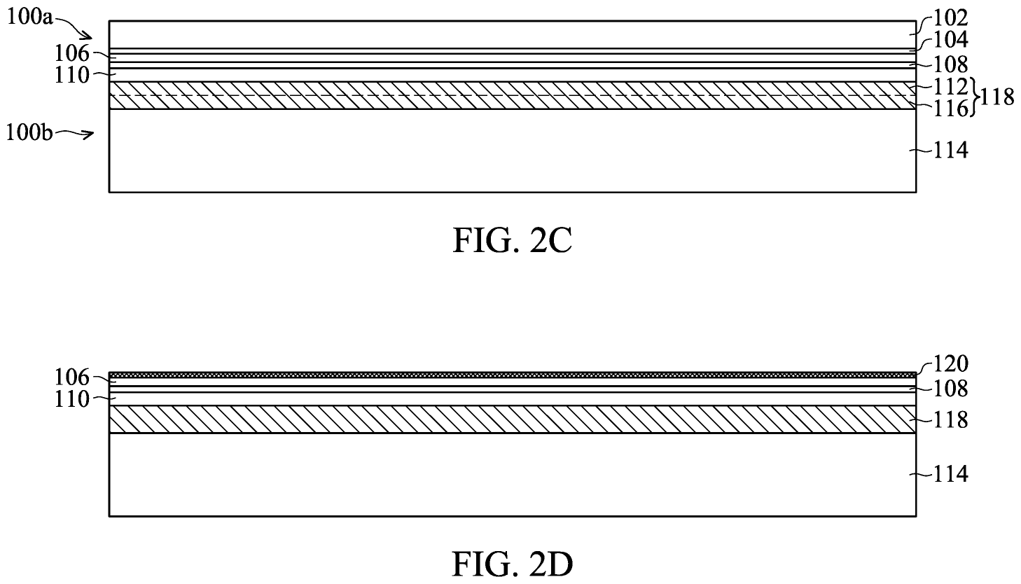

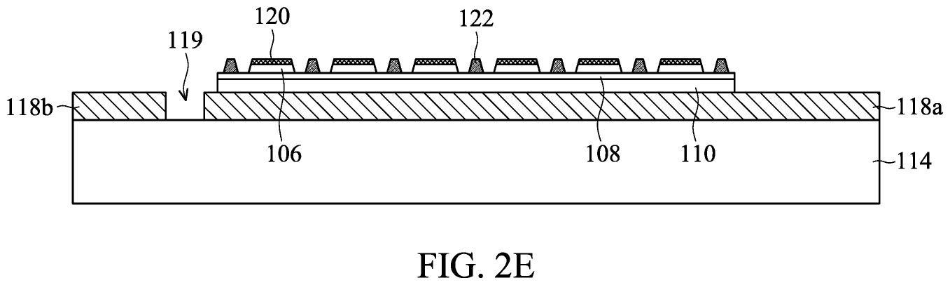

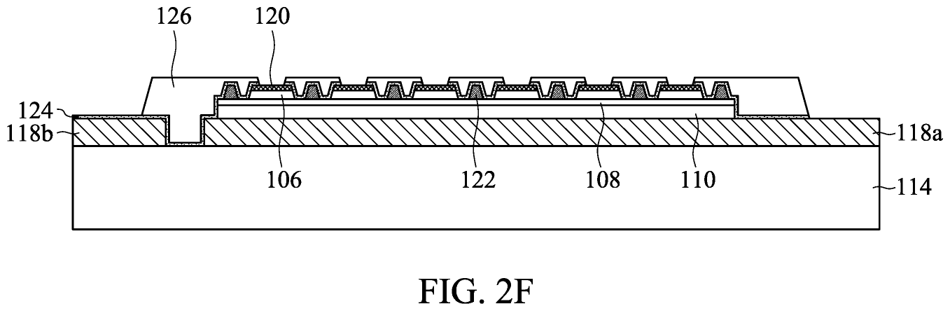

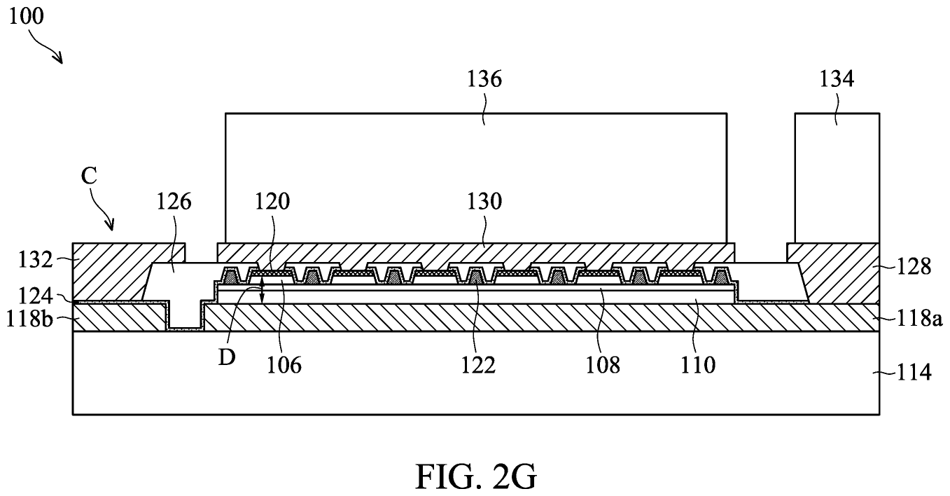

FIGS. 2A to 2G are cross-sectional views of various stages of manufacturing a heterojunction bipolar transistor (HBT) device 100 in accordance with some embodiments of the present disclosure. Additional features can be added to the HBT device 100. Some of the features described below can be replaced or eliminated for different embodiments. To simplify the diagram, only a portion of the HBT device 100 is illustrated.

As shown in FIG. 2A, a first structure 100a is provide, in accordance with some embodiments. The first structure 100a may include a carrier substrate 102, which may be formed of III-V compound semiconductor materials, including GaN, AlGaN, AlN, GaAs, AlGaAs, InP, InAlAs, InGaAs, the like, or a combination thereof, or any suitable material. As used herein, the term “III-V semiconductor” may refer to those semiconducting compounds formed between the elements in group III and the elements in group V of the periodic table, including aluminum (Al), gallium (Ga), indium (In), nitrogen (N), phosphorus (P), arsenic (As), the like, or a combination thereof. The term may also refer to ternary and quaternary compounds, such as AlGaN, AlInGaN, or the like. In some embodiments, the carrier substrate 102 may be made of GaAs.

A release layer 104 may be formed on the carrier substrate 102. The release layer 104 may be formed of a material which may be selectively removed (such as etched or dissolved) faster than the overlying layers. In some embodiments, the release layer 104 is formed of AlAs. Then, an emitter layer 106 is formed on the release layer 104, in accordance with some embodiments. The emitter layer 106 may be formed of III-V semiconductors, including GaN, AlGaN, AlN, GaAs, AlGaAs, InP, InAlAs, InGaAs, the like, or a combination thereof.

The emitter layer 106 may have a first conductivity type, such as n type. The emitter layer 106 may be formed by a deposition process, including molecular-beam epitaxy (MBE), liquid phase epitaxy (LPE), metalorganic chemical vapor deposition (MOCVD), chemical vapor deposition (CVD), hydride vapor phase epitaxy (HVPE), metal organic vapor phase epitaxy (MOVPE), the like, or a combination thereof.

In some embodiments, the emitter layer 106 is an n-type InGaP layer. In some other embodiments, the emitter layer 106 is a multi-layer structure with different doping concentrations. For example, the emitter layer 106 may include an n-type InGaP layer and a heavily-doped n-type GaAs layer which are stacked vertically.

Next, a base layer 108 is formed on the emitter layer 106, in accordance with some embodiments. The base layer 108 may be formed of III-V semiconductors, including GaN, AlGaN, AlN, GaAs, AlGaAs, InP, InAlAs, InGaAs, GaSb, the like, or a combination thereof. The emitter layer 106 and the base layer 108 may be formed of different materials with different band gaps, so that a heterojunction may be formed at the interface therebetween.

The base layer 108 may have a second conductivity type different from the first conductivity type, such as p type. The base layer 108 may be doped by C, Mg, Zn, Ca, Be, Sr, Ba, Ra, or any suitable materials. In some embodiments, the base layer 108 includes a heavily-doped p-type GaAs layer. The base layer 108 may be formed by a deposition process, including MBE, LPE, MOCVD, CVD, HVPE, MOVPE, the like, or a combination thereof.

Then, a collector layer 110 is formed on the base layer 108, in accordance with some embodiments. The collector layer 110 may be formed of III-V semiconductors, including GaN, AlGaN, AlN, GaAs, AlGaAs, InP, InAlAs, InGaAs, GaSb, the like, or a combination thereof. The collector layer 110 may have the first conductivity type, such as n type. The collector layer 110 may be formed by a deposition process, including MBE, LPE, MOCVD, CVD, HVPE, MOVPE, the like, or a combination thereof.

In some embodiments, the collector layer 110 is an n-type GaAs layer. In some other embodiments, the collector layer 110 is a multi-layer structure with different doping concentrations. For example, the collector layer 110 may include an n-type GaAs layer and a heavy-doped n-type InGaAs layer which are stacked vertically.

Next, a first metal layer 112 is formed on the collector layer 110, in accordance with some embodiments. The first metal layer 112 may be formed of gold (Au), copper (Cu), any suitable material, an alloy thereof, or a combination thereof. The first metal layer 112 may be formed by electroplating, sputtering, e-beam evaporation, physical vapor deposition (PVD), chemical vapor deposition (CVD), atomic layer deposition (ALD), the like, or a combination thereof.

Then, as illustrated in FIG. 2B, a second structure 100b is provided, in accordance with some embodiments. The second structure 100b may include a substrate 114. The substrate 114 may be a semiconductor substrate. The substrate 114 may be formed of III-V semiconductors, including GaN, AlGaN, AlN, GaAs, AlGaAs, InP, InAlAs, InGaAs, the like, or a combination thereof. In some embodiments, the substrate 114 is formed of undoped GaAs.

Next, a second metal layer 116 is formed on the substrate 114, in accordance with some embodiments. The second metal layer 116 may be formed of Au, Cu, any suitable material, an alloy thereof, or a combination thereof. The second metal layer 116 may be formed by electroplating, sputtering, e-beam evaporation, PVD, CVD, ALD, the like, or a combination thereof.

Then, as illustrated in FIG. 2C, the first structure 100a is flipped upside down and disposed over the second structure 100b, in accordance with some embodiments. The second metal layer 116 of the second structure 100b may be in contact with the first metal layer 112 of the first structure 100a. The second metal layer 116 and the first metal layer 112 may include the same material. Next, the first structure 100a may be bonded onto the second structure 100b, and the second metal layer 116 and the first metal layer 112 may form a metal layer 118.

Then, as illustrated in FIG. 2D, the carrier substrate 102 and the release layer 104 are removed from the emitter layer 106, in accordance with some embodiments. The carrier substrate 102 and the release layer 104 may be removed by etching away the release layer 104 during a lift-off process. In some embodiments, the release layer 104 is etched through a wet etchant, including hydrofluoric acid (HF) or any suitable etchant. The emitter layer 106 may be exposed.

Next, a material of emitter electrodes 120 is formed on the emitter layer 106, in accordance with some embodiments. The material of emitter electrodes 120 may be formed of titanium (Ti), aluminum (Al), cobalt (Co), nickel (Ni), Au, palladium (Pd), platinum (Pt), Cu, tungsten (W), the like, an alloy thereof, or a combination thereof. The material of emitter electrodes 120 may be formed by electroplating, sputtering, e-beam evaporation, PVD, CVD, ALD, the like, or a combination thereof.

Then, as illustrated in FIG. 2E, the material of emitter electrodes 120, the emitter layer 106, the base layer 108, the collector layer 110 are patterned by a photolithography and an etching process, in accordance with some embodiments. The photolithography process may include photoresist coating (e.g., spin-on coating), soft baking, mask aligning, exposure, post-exposure baking (PEB), photoresist development, rinsing, drying (e.g., hard baking), other suitable techniques, or a combination thereof. The etching process may include a dry etching process, a wet etching process, or a combination thereof. For example, the dry etching process may include reactive ion etch (RIE), inductively-coupled plasma (ICP) etching, neutral beam etch (NBE), electron cyclotron resonance (ERC) etching, the like, or a combination thereof. The wet etching process may use, for example, hydrofluoric acid (HF), ammonium hydroxide (NH₄OH), or any suitable etchant.

It should be noted that 6 emitter electrodes 120 in FIG. 2D are for illustrative purposes only, different number of the emitter electrodes 120 may be formed on the base layer 108. In particular, the power cell according to the present disclosure should include at least 5 emitter electrodes 120. For example, 8 emitter electrodes 120 may be formed on the base layer 108.

The sidewalls of the emitter electrodes 120 may be substantially aligned with the sidewalls of the emitter layer 106. The emitter electrodes 120 and the emitter layer 106 may be included in emitter mesas. The sidewalls of the base layer 108 may be substantially aligned with the sidewalls of the collector layer 110. The collector layer 110 and the base layer 108 may be included in a base mesa.

Next, a base electrode 122 is formed on the base layer 108 and between the emitter electrodes 120, in accordance with some embodiments. The base electrode 122 may be formed of Ti, Al, Co, Ni, Au, Pd, Pt, Cu, W, the like, an alloy thereof, or a combination thereof. The base electrode 122 may be formed by electroplating, sputtering, e-beam evaporation, PVD, CVD, ALD, the like, or a combination thereof. Then, the base electrode 122 may be patterned by a photolithography and an etching process. Examples of the photolithography and the etching process may be the same as or similar to those described above, and will not be repeated.

Next, the metal layer 118 is patterned and an opening 119 is formed, in accordance with some embodiments. The opening 119 may extend though the metal layer 118 and may expose the substrate 114, so that the metal layer 118 may be divided into a metallic sub-collector layer 118a and a metal layer 118b. The metal layer 118 may be patterned by a photolithography and an etching process. The metallic sub-collector layer 118a may be included in a collector mesa. The base electrode 122 and the emitter electrodes 120 may overlap the base layer 108, the collector layer 110, and the metallic sub-collector layer 118a.

Then, as illustrated in FIG. 2F, a dielectric layer 124 is formed conformally on the metallic sub-collector layer 118a, the metal layer 118b, the emitter electrodes 120, the base layer 108, the base electrode 122, and the substrate 114, in accordance with some embodiments. The dielectric layer 124 may protect the layers below, and provide physical isolation and structure support. The dielectric layer 124 may be formed of dielectric materials, including silicon nitride (Si₃N₄), silicon dioxide (SiO₂), silicon oxynitride (SiOₓN_{y}), the like, or a combination thereof. The dielectric layer 124 may be formed by a deposition process, including spin coating, CVD, ALD, MOCVD, the like, or a combination thereof.

Then, a passivation layer 126 is formed on the dielectric layer 124, in accordance with some embodiments. The passivation layer 126 may be formed of organic or inorganic insulating materials, such as silicon oxide, silicon nitride, silicon oxynitride, polyimide (PI), benzocyclobutene (BCB), polybenzoxazole (PBO), the like, or a combination thereof. In some embodiments, the materials used in dielectric layer 124 and passivation layer 126 may be different. The passivation layer 126 may be formed by a deposition process, including spin coating, CVD, ALD, MOCVD, the like, or a combination thereof.

Next, the passivation layer 126 is patterned to partially expose the top surfaces of the emitter electrodes 120, the top surface of the dielectric layer 124, and the top surface of the metallic sub-collector layer 118a, in accordance with some embodiments. The passivation layer 126 may be patterned by a photolithography and an etching process. Examples of the photolithography and the etching process may be the same as or similar to those described above, and will not be repeated.

Then, as illustrated in FIG. 2G, a metallic material layer is formed on the passivation layer 126, the dielectric layer 124, the emitter electrodes 120, and the metallic sub-collector layer 118a and is then patterned into a plurality of metal layers 128, 130 and 132, in accordance with some embodiments. The metallic material layer may be formed of Ti, Al, Co, Ni, Au, Pd, Pt, Cu, W, the like, an alloy thereof, or a combination thereof. The metallic material layer may be formed by electroplating, sputtering, e-beam evaporation, PVD, CVD, ALD, the like, or a combination thereof, and may be patterned by a photolithography and an etching process. Examples of the photolithography and the etching process may be the same as or similar to those described above, and will not be repeated.

The metal layer 128 may be electrically connected to the metallic sub-collector layer 118a, and thus may also be referred to as a collector contact. The metal layer 130 may be electrically connected to each of the emitter electrodes 120.

The metal layer 132, the metal layer 118b, and the dielectric layer 124 disposed therebetween may form a passive component C, such as a capacitor, and additional process is not required. The metal layer 118b (i.e., the bottom metal layer of the passive component C) may be formed of the same material as the metallic sub-collector layer 118a. The passive component C and the collector contact 128 may be disposed on opposite sides of the base layer 108 as illustrated in FIG. 2G, but the present disclosure is not limited thereto. The position of the passive component C may be adjusted by mask patterns.

The shortest distances from each of the emitter electrodes 120 to the metallic sub-collector layer 118a may be substantially same. In particular, the distance from one of the emitter electrodes 120 to the metallic sub-collector layer 118a may be the sum of the thickness of the emitter layer 106, the thickness of the base layer 108, and the thickness of the collector layer 110.

As illustrated in FIG. 2G, a plurality of emitter electrodes 120 may be disposed vertically over the metallic sub-collector layer 118a, so that the power cell can be achieved without increasing the parasitic capacitance between the emitter electrodes 120 and the metallic sub-collector layer 118a (Cce). Furthermore, an emitter shunt can be achieved from above the HBT device 100 while a collector shunt can be achieved from below the HBT device 100.

Moreover, the resistance contributed by a lateral epitaxial in a current path from metallic sub-collector 118a to each of the emitter electrodes 120 would substantially not exist. Therefore, the performances of each emitter are substantially the same, which results in better performance uniformity of the power cell HBT device 100. In addition, in comparison with the embodiment where a plurality of collector contacts are disposed between a plurality of emitter electrodes, the HBT device 100 according to some embodiments of the present disclosure can include one collector contact 128 disposed on one side of the emitter electrodes 120. Therefore, the occupied area and the number of the collector contact 128 can be reduced, results in reducing wafer size or die size. Furthermore, the metallic sub-collector layer 118a can also be adopted in a PN diode, a PIN diode, or any suitable devices.

Next, a plurality of conductive bumps 134 and 136 are formed on the metal layers 128 and 130, respectively, in accordance with some embodiments. The conductive bumps 134 and 136 may be formed of conductive materials, including solder, Cu, Al, Au, Ni, Ag, Pd, tin (Sn), tin-lead (Sn—Pb), indium (In), the like, an ally thereof, or a combination thereof. The conductive bumps 134 and 136 may be formed by electroplating, electroless plating, sputtering, printing, evaporation, CVD, the like, or a combination thereof. The conductive bump 134 may be electrically connected to the metallic sub-collector layer 118a through the metal layer 128. The conductive bump 136 may be electrically connected to the emitter electrodes 120 through the metal layer 130.

According to some embodiments, the metal layer 128 is not formed between the conductive bump 134 and the metallic sub-collector layer 118a. The conductive bump 134 may be in contact with the metallic sub-collector layer 118a. The conductive bump 134 may extend on the sidewall of the dielectric layer 124 and the sidewall of the passivation layer 126.

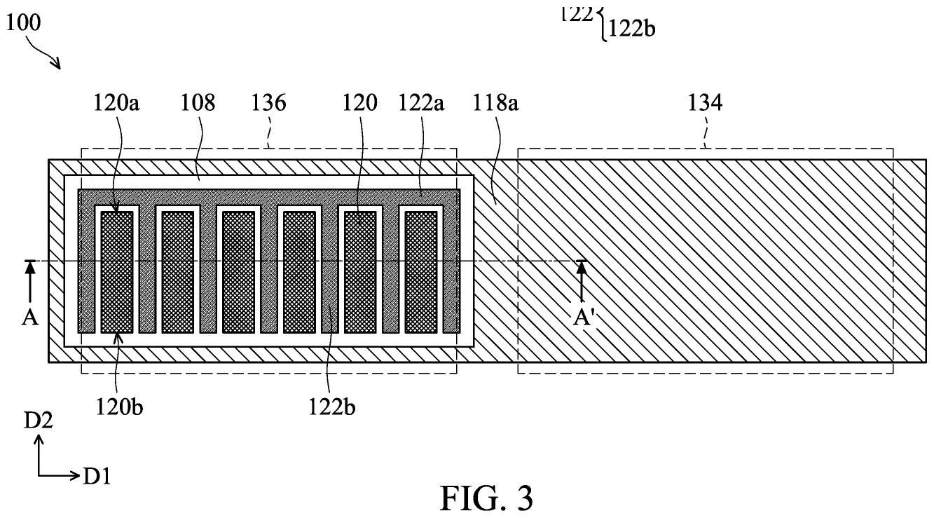

FIG. 3 is a top view of the HBT device 100 of FIG. 2G, in accordance with some embodiments. FIG. 2G is a cross-sectional view of the HBT device 100 taken along line A-A′ shown in FIG. 3. To simplify the figure, some components in FIG. 2G are omitted in FIG. 3. For example, the capacitor C, the substrate 114, and the dielectric layer 124 are not illustrated in FIG. 3.

As illustrated in FIG. 3, the metallic sub-collector layer 118a may extend in a first direction D1. The conductive bumps 134 and 136 may be arranged along the first direction D1. To clarify, the conductive bumps 134 and 136 are shown in dashed lines to reveal the underlying components. The emitter electrodes 120 may extend in a second direction D2 and may be arranged along the first direction D1. The second direction D2 may be perpendicular to the first direction D1. The angle between the first direction D1 and the second direction D2 may be 85 to 95 degrees. Each of the emitter electrodes 120 may have a strip shape, and thus may also be referred to as emitter strips.

The base electrode 122 may have a comb shape, which may include a plurality of base fingers 122b connected by a base strip 122a. Each of the base fingers 122b may extend in the second direction D2, and the base strip 122a may extend in the first direction D1. The base fingers 122b may be arranged in such a way that they alternate with the emitter electrodes 120. The emitter electrodes 120 may have a first short edge 120a surrounded by the base strip 122a and a second short edge 120b exposed. The second short edge 120b of the emitter electrodes 120 may be substantially aligned with an edge of the base fingers 122b.

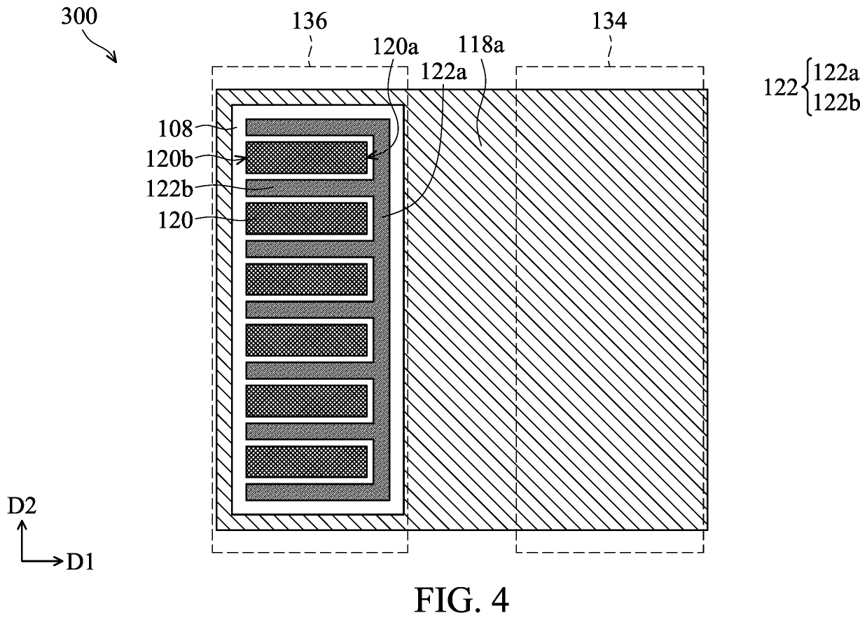

FIG. 4 is a top view of a HBT device 300, in accordance with some embodiments. It should be noted that the HBT device 300 may include the same or similar components as those of the HBT device 100, which is illustrated in FIG. 3, and for the sake of simplicity, those components will not be discussed in detail again. In the following embodiments, the base electrode 122 and the emitter electrodes 120 are arranged in the different direction.

As illustrated in FIG. 4, the conductive bumps 134 and 136 may be arranged along the first direction D1. The emitter electrodes 120 may extend in the first direction D1, and may be arranged along the second direction D2. The base electrode 122 may include a plurality of base fingers 122b connected by a base strip 122a. Each of the base fingers 122b may extend in the first direction D1, and the base strip 122a may extend in the second direction D2. The base fingers 122b may be arranged in such a way that they alternate with the emitter electrodes 120. The base strip 122a may be disposed closer to the conductive bump 134 than the base fingers 122b.

The emitter electrodes 120 may have a first short edge 120a surrounded by the base strip 122a and a second short edge 120b exposed. The distance between the second short edge 120b of the emitter electrodes 120 and the conductive bump 134 may be greater than the distance between the first short edge 120a of the emitter electrodes 120 and the conductive bump 134.

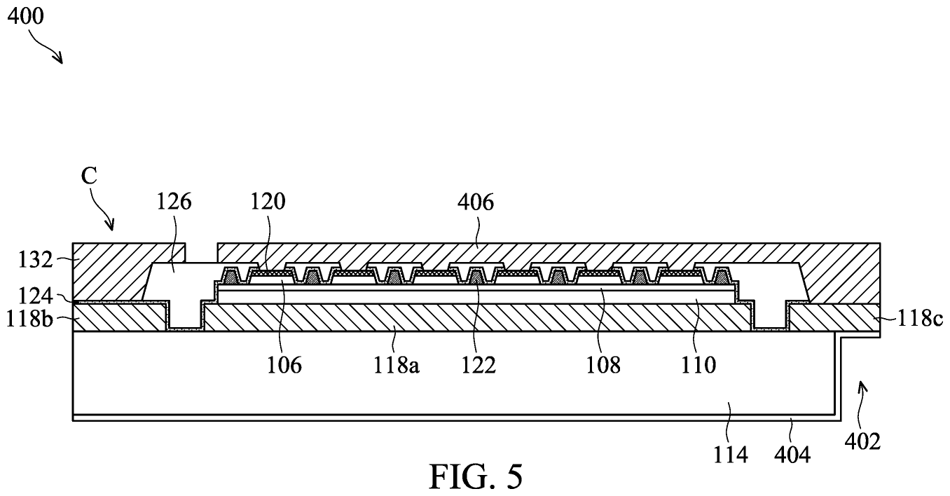

FIG. 5 is a cross-sectional view of a HBT device 400, in accordance with some embodiments. It should be noted that the HBT device 400 may include the same or similar components as those of the HBT device 100, which is illustrated in FIG. 2G, and for the sake of simplicity, those components will not be discussed in detail again. In the following embodiments, the emitter electrodes are electrically connected to a backside metal layer through a backside via.

As illustrated in FIG. 5, the metal layer 118 illustrated in FIG. 2D is patterned into a metallic sub-collector layer 118a, a metal layer 118b, and a metal layer 118c, in accordance with some embodiments. The metal layer 118b and the metal layer 118c may be formed of the same material as the metallic sub-collector layer 118a. The metal layer 118b and the metal layer 118c may be disposed on opposite sides of the metallic sub-collector layer 118a. A backside via 402 may be formed in the substrate 114 by an etching process. The backside via 402 may extend through the substrate 114 and may partially expose the bottom surface of the metal layer 118c.

A backside metal layer 404 may be formed on the bottom surface of the substrate 114 and may extend to the metal layer 118c along a sidewall of the backside via 402. The backside metal layer 404 may connect to the metal layer 118c. The backside metal layer 404 may be formed of Ti, Al, Co, Ni, Au, Pd, Pt, Cu, W, the like, an alloy thereof, or a combination thereof. The backside metal layer 404 may be formed by electroplating, sputtering, e-beam evaporation, PVD, CVD, ALD, the like, or a combination thereof. In some embodiments, the backside metal layer 404 is patterned to form one or more hot vias.

The metallic material layer formed on the passivation layer 126 may be patterned into a metal layer 132 and a metal layer 406. The metal layer 406 may electrically connect the emitter electrodes 120 to the metal layer 118c, and may further be electrically connected to the backside metal layer 404.

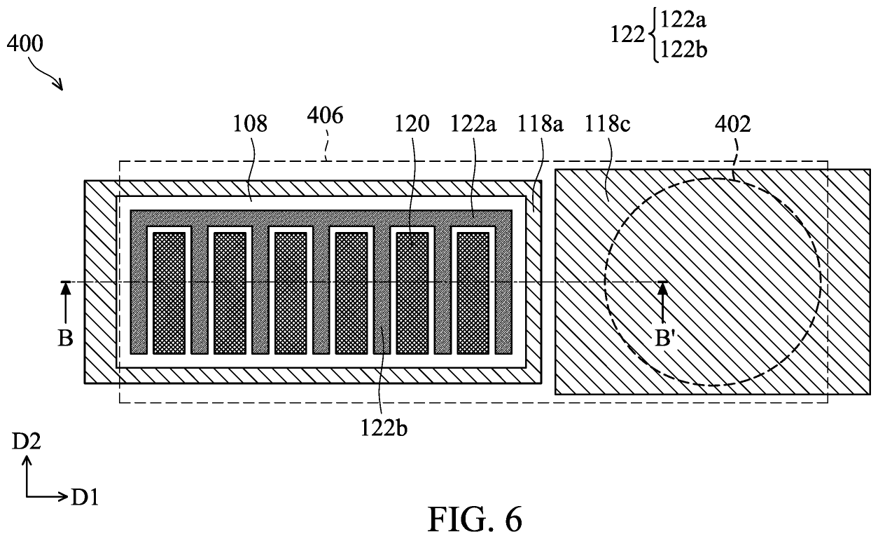

FIG. 6 is a top view of the HBT device 400 of FIG. 5, in accordance with some embodiments. FIG. 5 is a cross-sectional view of the HBT device 400 taken along line B-B′ shown in FIG. 6. To simplify the figure, some components in FIG. 5 are omitted in FIG. 6. For example, the capacitor C, the substrate 114, the dielectric layer 124, and the backside metal layer 404 are not illustrated in FIG. 6. The HBT device 400 in FIG. 6 may include the same or similar components as those of the HBT device 100 in FIG. 3, and for the sake of simplicity, those components will not be discussed in detail again.

As illustrated in FIG. 6, the metallic sub-collector layer 118a and the metal layer 118c may be arranged along the first direction D1. The metal layer 406 may extend in the first direction D1 and may overlap the metallic sub-collector layer 118a, the metal layer 118c, and the backside via 402. However, the position of the backside via 402 is for illustrative purposes only. For example, the backside via 402 may be disposed closer to the base strip 122a than the base fingers 122b.

In summary, the HBT device according to the present disclosure includes a metallic sub-collector layer and a plurality of emitter electrodes vertically overlap the metallic sub-collector layer. As a result, better performance uniformity of the power cell HBT can be achieved. Furthermore, both of the emitter shunt and the collector shunt can be achieved. In addition, the occupied area and the number of the collector contact can be reduced, results in reducing wafer size or die size. Moreover, one or more passive components can be formed without additional processes.

While the present disclosure has been described by way of example and in terms of the preferred embodiments, it should be understood that the present disclosure is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A heterojunction bipolar transistor device, comprising:
a substrate;
a metallic sub-collector layer formed over the substrate;
a collector layer formed over the metallic sub-collector layer;
a base layer formed over the collector layer;
an emitter layer formed over the base layer;
a base electrode formed over the base layer and comprising a plurality of base fingers; and
a plurality of emitter strips formed over the emitter layer and arranged alternately with the plurality of base fingers.

2. The heterojunction bipolar transistor device as claimed in claim 1, further comprising:
a single base mesa comprising the collector layer and the base layer, wherein the plurality of emitter strips are disposed over the single base mesa.

3. The heterojunction bipolar transistor device as claimed in claim 1, further comprising:
a metal layer formed over and electrically connected to the plurality of emitter strips.

4. The heterojunction bipolar transistor device as claimed in claim 1, further comprising:
a first conductive bump formed over and electrically connected to the plurality of emitter strips.

5. The heterojunction bipolar transistor device as claimed in claim 4, further comprising:
a second conductive bump formed over and electrically connected to the metallic sub-collector layer in an area outside the collector layer.

6. The heterojunction bipolar transistor device as claimed in claim 5, further comprising:
a collector contact formed between the metallic sub-collector layer and the second conductive bump.

7. The heterojunction bipolar transistor device as claimed in claim 5, wherein the plurality of emitter strips are arranged in a first direction, and the first conductive bump and the second conductive bump are arranged in a second direction different from the first direction in a top view.

8. The heterojunction bipolar transistor device as claimed in claim 5, wherein the plurality of emitter strips are arranged in a direction, and the first conductive bump and the second conductive bump are arranged in the direction in a top view.

9. The heterojunction bipolar transistor device as claimed in claim 1, further comprising:
a passive component formed over the substrate in an area outside the collector layer, wherein the passive component comprises a bottom metal layer formed of the same material as the metallic sub-collector layer.

10. The heterojunction bipolar transistor device as claimed in claim 1, further comprising:
a dielectric layer formed over the substrate and covering sidewalls of the collector layer, the base layer, the emitter layer, and the metallic sub-collector layer.

11. The heterojunction bipolar transistor device as claimed in claim 10, wherein the dielectric layer further covers a sidewall and a top surface of the base electrode.

12. The heterojunction bipolar transistor device as claimed in claim 1, wherein the plurality of emitter strips and the plurality of base fingers are arranged along a width direction of the base layer.

13. The heterojunction bipolar transistor device as claimed in claim 1, wherein each of the emitter strips overlaps the metallic sub-collector layer.

14. The heterojunction bipolar transistor device as claimed in claim 1, wherein shortest distances from each of the emitter strips to the metallic sub-collector layer are substantially same.

15. The heterojunction bipolar transistor device as claimed in claim 1, further comprising:
a backside via formed in the substrate; and
a backside metal layer extending from a top surface of the substrate to a bottom surface of the substrate along a sidewall of the backside via and connecting to a metal layer formed of the same material as the metallic sub-collector layer.

16. The heterojunction bipolar transistor device as claimed in claim 15, further comprising:
a metal layer electrically connected to the plurality of emitter strips and vertically overlapping the backside via.

17. A heterojunction bipolar transistor device, comprising:
a substrate;
a collector mesa formed on the substrate and comprising a metallic sub-collector layer;
a base mesa formed on the collector mesa;
a plurality of emitter mesas formed on the base mesa; and
a base electrode formed on the base mesa and comprising a plurality of base fingers arranged alternately with the plurality of emitter mesas.

18. The heterojunction bipolar transistor device as claimed in claim 17, further comprising:
a passive component formed over the substrate on a first side of the base mesa and comprising a bottom metal layer formed of the same material as the metallic sub-collector layer.

19. The heterojunction bipolar transistor device as claimed in claim 17, further comprising:
a collector contact formed over the metallic sub-collector layer on a second side of the base mesa.

20. The heterojunction bipolar transistor device as claimed in claim 17, wherein the plurality of emitter mesas overlap the base mesa and the metallic sub-collector layer.
